(19) United States
(12) Patent Application Publication
(10) Pub. No.: US 2026/0164552 A1
(43) Pub. Date: Jun. 11, 2026

(54) PRINTED CIRCUIT BOARD

(71) Applicant: SAMSUNG ELECTRO-MECHANICS CO., LTD., Suwon-si (KR)

(72) Inventors: Jin Uk LEE, Suwon-si (KR); Koo Woong JEONG, Suwon-si (KR)

(73) Assignee: SAMSUNG ELECTRO-MECHANICS CO., LTD., Suwon-si (KR)

(21) Appl. No.: 19/179,529

(22) Filed: Apr. 15, 2025

(30) Foreign Application Priority Data
Aug. 26, 2024 (KR) 10-2024-0114348

(51) Int. Cl. H05K 1/11; H05K 1/185; H10W 70/685

(52) U.S. Cl. CPC H05K 1/115; H05K 1/185; H10W 70/685; H05K 2201/09563

(57) ABSTRACT

A printed circuit board includes a substrate body including a plurality of wiring layers and a plurality of via layers, wherein the plurality of wiring layers include a pair of first wiring patterns spaced apart from each other and disposed at substantially the same level as each other with respect to a thickness direction; and a first redistribution unit including one or more first redistribution layers, wherein the one or more first redistribution layers include a first redistribution pattern disposed at a level different from a level of the pair of first wiring patterns with respect to the thickness direction, wherein the first redistribution unit is embedded in the substrate body, and wherein the first redistribution pattern connects the pair of first wiring patterns to each other.

### CROSS-REFERENCE TO RELATED APPLICATIONS

This application claims benefit of priority to Korean Patent Application No. 10-2024-0114348 filed on Aug. 26, 2024 in the Korean Intellectual Property Office, the disclosure of which is incorporated herein by reference in its entirety.

### BACKGROUND

### 1. Field

The present disclosure relates to a printed circuit board.

### 2. Description of Related Art

Recently, as the number of semiconductor chips mounted on a package substrate increases, an area of a substrate has increased, and also, as the number of wirings increases, the number of layers of a substrate has also increased. For example, as the number of wirings increases, tangles between the wirings may increase, and in order to release tangles, separation of wiring layers may be necessary. Accordingly, the number of layers of a substrate may increase. Also, it may be necessary to insert a ground layer between the wiring layers separated from each other, and accordingly, the number of layers may further increase. Also, a multilayer package substrate may be manufactured using a double-sided lamination method with respect to a core layer, and in this case, the number of layers may also increase on the opposite side. Such an increase in the number of substrate layers may increase the manufacturing time and cost, and may also lead to a decrease in yield.

### SUMMARY

An aspect of the present disclosure is to provide a printed circuit board which may effectively relieve wiring tangles and may thus reduce an increase in the number of layers.

An aspect of the present disclosure is to provide a printed circuit board which may integrate layer-separated wirings into a single layer using a redistribution unit including a redistribution pattern.

According to an example embodiment, a printed circuit board includes a substrate body including a plurality of wiring layers and a plurality of via layers, wherein the plurality of wiring layers include a pair of first wiring patterns spaced apart from each other and disposed at substantially the same level as each other with respect to a thickness direction; and a first redistribution unit including one or more first redistribution layers, wherein the one or more first redistribution layers include a first redistribution pattern disposed at a level different from a level of the pair of first wiring patterns with respect to the thickness direction, wherein the first redistribution unit is embedded in the substrate body, and wherein the first redistribution pattern connects the pair of first wiring patterns to each other.

According to an example embodiment, a printed circuit board includes a pair of first wiring patterns disposed and spaced apart from each other on substantially the same layer; a pair of second wiring patterns disposed and spaced apart from each other on substantially the same layer; a first redistribution unit including a first redistribution pattern disposed in a different layer from the pair of first wiring patterns and connecting the pair of first wiring patterns to each other; and a second redistribution unit including a second redistribution pattern disposed in a different layer from the pair of second wiring patterns and connecting the pair of second wiring patterns to each other.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram illustrating an example of an electronic device system;

FIG. 2 is a perspective diagram illustrating an example of an electronic device;

FIG. 3 is a plan diagram illustrating a printed circuit board according to an example embodiment;

FIG. 4 is a cross-sectional diagram illustrating the printed circuit board illustrated in FIG. 3 taken along line I-I′;

FIG. 5 is a cross-sectional diagram illustrating the printed circuit board illustrated in FIG. 3 taken along line II-II′;

FIG. 6 is a cross-sectional diagram illustrating an example of a redistribution unit according to an example embodiment;

FIG. 7 is a cross-sectional diagram illustrating another example of a redistribution unit according to an example embodiment according to an example embodiment;

FIG. 8 is a cross-sectional diagram illustrating another example of a printed circuit board according to another example embodiment according to an example embodiment;

FIG. 9 is a cross-sectional diagram illustrating another example of a printed circuit board according to another example embodiment according to an example embodiment;

FIG. 10 is a cross-sectional diagram illustrating another example of a printed circuit board according to another example embodiment according to an example embodiment; and

FIG. 11 is a cross-sectional diagram illustrating another example of a printed circuit board according to another example embodiment according to an example embodiment.

### DETAILED DESCRIPTION

Hereinafter, embodiments of the present disclosure will be described as follows with reference to the attached drawings. Some elements may be exaggerated, omitted or briefly illustrated, and the sizes of the elements do not necessarily reflect the actual sizes of these elements.

### Electronic Device

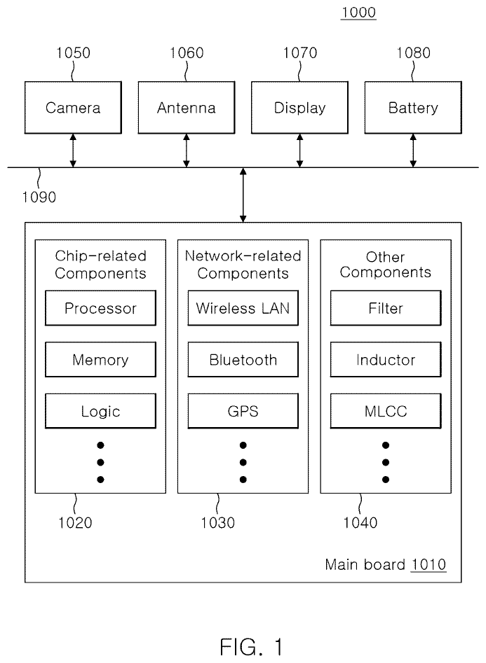

FIG. 1 is a block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, and may also include a variety of other wireless or wired standards or protocols. Also, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive components used for various other purposes, or the like. Also, other components 1040 may be combined with each other, together with the chip related components 1020 and/or the network related components 1030 described above.

Depending on a type of the electronic device 1000, the electronic device 1000 may include other components which may or may not be physically or electrically connected to the mainboard 1010. The other components may include, for example, a camera module 1050, an antenna module 1060, a display 1070, and a battery 1080. However, the other components are not limited thereto, and may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. The other components may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device processing data.

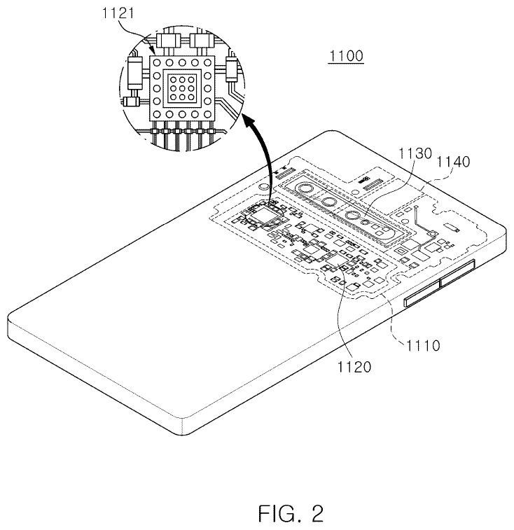

FIG. 2 is a perspective diagram illustrating an example of an electronic device.

Referring to FIG. 2, an electronic device may be a smartphone 1100, for example. A motherboard 1110 may be accommodated in the smartphone 1100, and various components 1120 may be physically or electrically connected to the motherboard 1110. Also, other components which may or may not be physically or electrically connected to the motherboard 1110, such as a camera module 1130, may be accommodated in the body 1101. A portion of the components 1120 may be the chip related components, such as, for example, a component package 1121, but an example embodiment example thereof is not limited thereto. The component package 1121 may have the form of a printed circuit board on which electronic components including active components and/or passive components are surface-mounted. Alternatively, the component package 1121 may be configured in the form of a printed circuit board in which active components and/or passive components are buried. The electronic device is not necessarily limited to the smartphone 1100, and may be other electronic devices as described above.

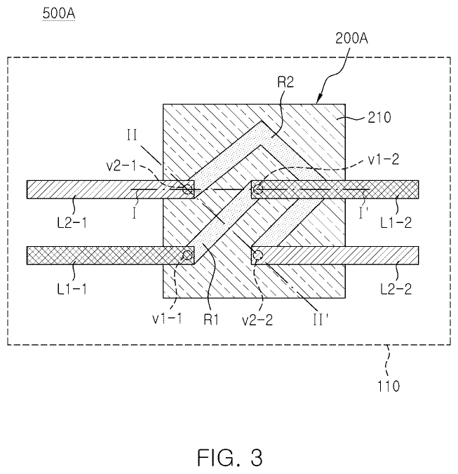

FIG. 3 is a plan diagram illustrating a printed circuit board according to an example embodiment.

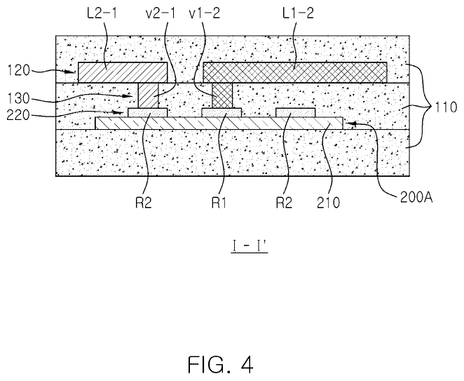

FIG. 4 is a cross-sectional diagram illustrating the printed circuit board illustrated in FIG. 3 taken along line I-I′.

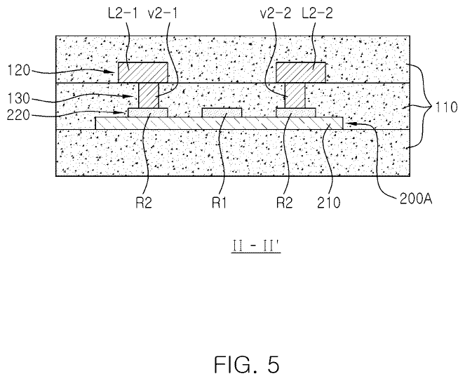

FIG. 5 is a cross-sectional diagram illustrating the printed circuit board illustrated in FIG. 3 taken along line II-II′.

Referring to the drawings, a printed circuit board 500A according to an example may include a substrate body 110, 120, and 130 including an insulating layer 110, a wiring layer 120, and a via layer 130, and a redistribution unit 200A built in the substrate body 110, 120, and 130 and including a dielectric layer 210 and a redistribution layer 220. The wiring layer 120 may include a pair of first wiring patterns L1-1 and L1-2 spaced apart from each other on substantially the same layer, for example, at substantially the same level in the thickness direction. The redistribution layer 220 may include a first redistribution pattern R1 disposed in a different layer, for example, at a different level in the thickness direction, from the pair of first wiring patterns L1-1 and L1-2. The via layer 130 may include a pair of first connection vias v1-1 and v1-2. The first redistribution pattern R1 may be connected to the pair of first wiring patterns L1-1 and L1-2 through the pair of first connection vias v1-1 and v1-2, respectively. Accordingly, the pair of first wiring patterns L1-1 and L1-2 may be connected through the first redistribution pattern R1.

The printed circuit board 500A may include a redistribution unit 200A including a first redistribution pattern R1 electrically connecting the pair of first wiring patterns L1-1 and L1-2 to each other. Accordingly, the pair of first wiring patterns L1-1 and L1-2, which may require layer-separation, may be formed on substantially the same layer without layer-separation. Accordingly, wiring tangles may be effectively resolved, and an increase in the number of layers may be reduced. Accordingly, the manufacturing time and cost of the substrate may be reduced, and a decrease in yield reduction may be reduced.

The wiring layer 120 may further include a pair of second wiring patterns L2-1 and L2-2 spaced apart from each other on substantially the same layer, for example, at substantially the same level with respect to the thickness direction. The pair of first wiring patterns L1-1 and L1-2 and the pair of second wiring patterns L2-1 and L2-2 may be disposed on substantially the same layer, for example, at substantially the same level with respect to the thickness direction. Also, the redistribution layer 220 may further include a second redistribution pattern R2 disposed in a different layer from the pair of second wiring patterns L2-1 and L2-2, for example, at a different level with respect to the thickness direction. The first redistribution pattern R1 and the second redistribution pattern R2 may be disposed substantially on the same layer, for example, substantially at the same level with respect to the thickness direction, but an embodiment thereof is not limited thereto, and the patterns may be disposed on different levels. The via layer 130 may further include a pair of second connections vias v2-1 and v2-2. The second redistribution pattern R2 may be connected to the pair of second wiring patterns L2-1 and L2-2, respectively, through the pair of second connections vias v2-1 and v2-2. Accordingly, the pair of second wiring patterns L2-1 and L2-2 may be connected through the second redistribution pattern R2.

In the printed circuit board 500A, the pair of first wiring patterns L1-1 and L1-2 and the pair of second wiring patterns L2-1 and L2-2, which may need layer-separation, may be disposed substantially on the same layer, and tangles of the wiring patterns may be effectively resolved through the first redistribution pattern R1 and the second redistribution pattern R2. Accordingly, wiring tangles may be resolved effectively, and an increase in the number of layers may be reduced. Accordingly, the manufacturing time and cost of the substrate may be reduced, and a decrease in yield may be reduced.

When the substrate bodies 110, 120, and 130 and the redistribution unit 200A are viewed from above, the second redistribution pattern R2 may overlap at least one of the pair of first wiring patterns L1-1 and L1-2. Accordingly arrangement, wiring tangles may be effectively resolved, and the increase in the number of layers may be reduced. Accordingly, the manufacturing time and cost of the substrate may be further reduced, and the yield reduction may be further reduced.

In the description below, the components of the printed circuit board 500A will be described in greater detail with reference to the drawings.

The insulating layer 110 may include an insulating material. The insulating material may include a thermosetting resin such as an epoxy resin and/or a thermoplastic resin such as a polyimide. Alternatively, the insulating material may include an inorganic filler, an organic filler, and/or a glass fiber (glass cloth, glass fabric) together with these resins. For example, the insulating material may be copper clad laminate (CCL), prepreg (PPG), Ajinomoto build-up film (ABF), photo imageable dielectric (PID), solder resist (SR), or the like, but an embodiment thereof is not limited thereto. The insulating layer 110 may include a plurality of layers, and may include the same insulating material or may include different insulating materials. The insulating layer 110 may have distinct boundaries therebetween, or may be integrated if desired such that the boundaries may not be distinct.

The wiring layer 120 may include a metal. The metal may include copper (Cu), aluminum (Al), silver (Ag), tin (Sn), gold (Au), nickel (Ni), lead (Pb), titanium (Ti), and/or alloys thereof. Preferably, the wiring layer 120 may include copper (Cu), but an embodiment thereof is not limited thereto. The wiring layer 120 may perform various functions depending on a design. For example, the wiring layer 120 may include a signal pattern, a power pattern, a ground pattern, or the like. Each of these patterns may have various shapes such as a line, a plane, a pad, or the like. The wiring layer 120 may include a seed layer and a plating layer. The seed layer may be formed by electroless plating of chemical copper, or the like, and may also be formed by a sputtering process if desired. Alternatively, both may be used. The plating layer may be formed by electrolytic plating of electrolytic copper, or the like. If desired, the wiring layer 120 may further include a copper foil in addition to the seed layer and the plating layer. The wiring layer 120 may include a plurality of layers. The plurality of wiring layers 120 may be disposed on or in the plurality of insulating layers 110, respectively.

The via layer 130 may include a metal. The metal may include copper (Cu), aluminum (Al), silver (Ag), tin (Sn), gold (Au), nickel (Ni), lead (Pb), titanium (Ti), and/or alloys thereof. Preferably, the via layer 130 may include copper (Cu), but an embodiment thereof is not limited thereto. The via layer 130 may include a plurality of connection vias. The plurality of connection vias may perform various functions depending on a design. For example, the via layer 130 may include a signal via, a power via, a ground via, or the like. The plurality of connection vias may include a filled via (filled VIA) in which the via-holes are filled with metal, or may also include a conformal via (conformal VIA) in which the metal is disposed along a wall surface of the via-hole. Also, various shapes of through-vias (through VIAs) may be included. Each of the plurality of connection vias may have a vertical shape, a tapered shape, and/or an hourglass shape on the cross-section. The via layer 130 may include a seed layer and a plating layer. The seed layer may be formed by electroless plating of chemical copper, or may be formed by a sputtering process if desired. Alternatively, both may be used. The plating layer may be formed by electrolytic plating of electrolytic copper, or may be formed by electrolytic plating of electrolytic copper. The via layer 130 may include a plurality of layers. The plurality of via layers 130 may be disposed in the plurality of insulating layers 110, respectively.

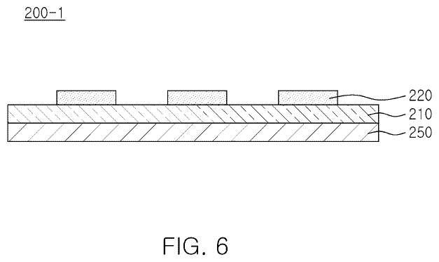

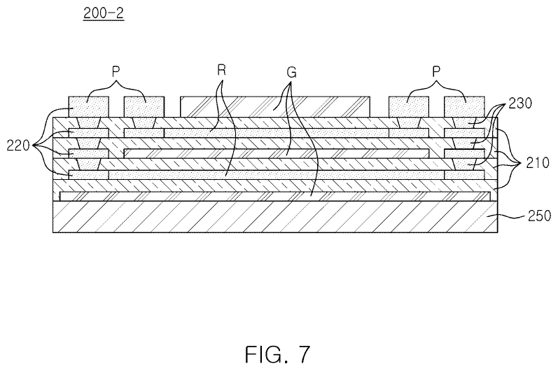

The redistribution unit 200A may be a sub-substrate embedded in the substrate body 110, 120, and 130. In terms of manufacturing process difficulty, cost reduction, embedding process difficulty, yield, or the like, the redistribution unit 200A may include an organic bridge structure, but an embodiment thereof is not limited thereto, and if desired, the redistribution unit 200A may include a silicon bridge substrate structure. The redistribution unit 200A may include a dielectric layer 210 and a redistribution layer 220 disposed on or in the dielectric layer 210. If desired, a redistribution via layer may be disposed in the dielectric layer 210. The redistribution unit 200A may be attached to at least one of the plurality of insulating layers 110 through an adhesive film such as a die attach film (DAF), and may be buried in at least another one of the plurality of insulating layers 110. The redistribution unit 200A may include a single-layer structure (see FIG. 6: 200-1) or a multilayer structure (see FIG. 7: 200-2). The further description of the components included in the redistribution unit 200A will be provided later.

FIG. 6 is a cross-sectional diagram illustrating an example of a redistribution unit according to an example embodiment.

Referring to the drawing, a redistribution unit 200-1 according to an example may be a single-layer structure including a dielectric layer 210 and a redistribution layer 220 disposed on the dielectric layer 210. An adhesive film 250 may be attached to a lower surface of the dielectric layer 210. For example, when tangles of the pair of first wiring patterns and the pair of second wiring patterns are relatively not severe or according to other needs, the first redistribution pattern for releasing tangles of the pair of first wiring patterns and the second redistribution pattern for releasing tangles of the pair of second wiring patterns may be spaced apart from each other at substantially the same level with respect to the thickness direction. For example, the first and second redistribution patterns may be formed in one redistribution layer 220.

The dielectric layer 210 may include an organic insulating material or an inorganic insulating material. The organic insulating material may include a thermosetting resin such as an epoxy resin and/or a thermoplastic resin such as a polyimide. Alternatively, the organic insulating material may include an inorganic filler together with these resins. For example, the organic insulating material may be an Ajinomoto build-up film (ABF), a photo imageable dielectric (PID), or the like, which are build-up materials of the substrate, but an embodiment thereof is not limited thereto. The inorganic insulating material may be silicon (Si), or the like, and may include, for example, silicon oxide or silicon nitride, but an embodiment thereof is not limited thereto.

The redistribution layer 220 may include a metal. The metal may include copper (Cu), aluminum (Al), silver (Ag), tin (Sn), gold (Au), nickel (Ni), lead (Pb), titanium (Ti), and/or alloys thereof. Preferably, the redistribution layer 220 may include copper (Cu), but an embodiment thereof is not limited thereto. The redistribution layer 220 may perform various functions depending on a design. For example, the redistribution layer 220 may include a signal pattern, a power pattern, a ground pattern, or the like. Each of these patterns may have various shapes such as a line, a plane, a pad, or the like. The redistribution layer 220 may include a seed layer and a plating layer. The seed layer may be formed by electroless plating, or may be formed by a sputtering process if desired, or both may be used. The plating layer may be formed by electrolytic plating, but an embodiment thereof is not limited thereto, and the plating layer may be formed by electroless plating and/or a sputtering process.

The adhesive film 250 may include various insulating materials having adhesive properties. For example, the adhesive film 250 may include epoxy resin, polyimide, silicone resin, or the like, but an embodiment thereof is not limited thereto. Metal particles such as copper (Cu) or silver (Ag) may be added to the adhesive film 250, but an embodiment thereof is not limited thereto. A die attach film (DAF) may be used the adhesive film 250, but an embodiment thereof is not limited thereto.

FIG. 7 is a cross-sectional diagram illustrating another example of a redistribution unit according to an example embodiment according to an example embodiment.

Referring to the drawings, a redistribution unit 200-2 according to another example may have a multilayer structure including a plurality of redistribution layers 220 disposed on or in a plurality of dielectric layers 210 and a plurality of redistribution via layers 230 disposed in the plurality of dielectric layers 210, respectively, and connecting the plurality of redistribution layers 220 to each other. An adhesive film 250 may be attached to a lower surface of the dielectric layer 210 on the lowest side among the plurality of dielectric layers 210. For example, when tangles of the pair of first wiring patterns and the pair of second wiring patterns are relatively severe or for other needs, the first redistribution pattern for resolving tangles of the pair of first wiring patterns and the second redistribution pattern for resolving tangles of the pair of second wiring patterns may be disposed at different levels with respect to the thickness direction. For example, the first and second redistribution patterns may be formed in the redistribution layers 220 of different layers, respectively.

Each of the plurality of dielectric layers 210 may include an organic insulating material or an inorganic insulating material. The organic insulating material may include a thermosetting resin such as an epoxy resin and/or a thermoplastic resin such as a polyimide. Alternatively, the organic insulating material may include an inorganic filler together with these resins. For example, the organic insulating material may be an Ajinomoto build-up film (ABF), a photo imageable dielectric (PID), or the like, which are build-up materials of the substrate, but an embodiment thereof is not limited thereto. The inorganic insulating material may be silicon (Si), or the like, and may include, for example, silicon oxide or silicon nitride, but an embodiment thereof is not limited thereto. The plurality of dielectric layers 210 may include the same insulating material, but an embodiment thereof is not limited thereto. The plurality of dielectric layers 210 may have distinct boundaries therebetween, but an embodiment thereof is not limited thereto, and the plurality of dielectric layers 210 may be integrated with each other such that the boundaries are unclear.

Each of the plurality of redistribution layers 220 may include a metal. The metal may include copper (Cu), aluminum (Al), silver (Ag), tin (Sn), gold (Au), nickel (Ni), lead (Pb), titanium (Ti), and/or alloys thereof. Preferably, the redistribution layer may include copper (Cu), but an embodiment thereof is not limited thereto. Each of the plurality of redistribution layers 220 may perform various functions depending on a design. For example, each of the plurality of redistribution layers 220 may include a signal pattern, a power pattern, a ground pattern, or the like. Each of these patterns may have various shapes such as a line, a plane, and a pad. Each of the plurality of redistribution layers 220 may include a seed layer and a plating layer. The seed layer may be formed by electroless plating, or if desired, by a sputtering process. Alternatively, both may be used. The plating layer may be formed by electroless plating, but an embodiment thereof is not limited thereto, and the plating layer may be formed by electroless plating and/or a sputtering process. The plurality of redistribution layers 220 may have a structure in which a redistribution layer 220 including a redistribution pattern R and a redistribution layer including a ground pattern G are alternately laminated, and in this case, electromagnetic interference may be effectively prevented.

Among the plurality of redistribution layers 220, the redistribution layer 220 disposed on the uppermost side may include a plurality of connection pads P and a ground pattern G disposed between the plurality of connection pads P. The plurality of connection pads P may include the pair of first connection pads connected to the pair of first wiring patterns, respectively, and the pair of second connection pads connected to the pair of second wiring patterns, respectively. The redistribution layer 220 disposed on the uppermost side may have a thickness greater than that of each of the other redistribution layers 220, and accordingly, connection between the pair of first connection vias and the pair of first connection pads and connection between the pair of second connection vias and the pair of second connection pads may be easily implemented.

Each of the plurality of redistribution via layers 230 may include a metal. The metal may include copper (Cu), aluminum (Al), silver (Ag), tin (Sn), gold (Au), nickel (Ni), lead (Pb), titanium (Ti), and/or alloys thereof. Preferably, each of the plurality of redistribution via layers 230 may include copper (Cu), but an embodiment thereof is not limited thereto. The plurality of redistribution via layer 230 may include one or more connection vias, respectively. The one or more connection vias may perform various functions depending on a design. For example, the connection vias may include a signal via, a power via, a ground via, or the like. The one or more connection vias may include a filled-via (filled VIA) in which a via-hole is filled with metal, or may also include a conformal via (conformal VIA) in which metal is disposed along a wall surface of the via-hole. The one or more connection vias included in the plurality of redistribution via layer 230 may be disposed in the form of a stacked VIA. Each of the one or more connection vias may penetrate one dielectric layer 210, or may also penetrate the plurality of dielectric layers 210 collectively if desired. Each of the one or more connection vias may have a vertical shape and/or a tapered shape in the cross-section. Each of the plurality of redistribution via layer 230 may include a seed layer and a plating layer. The seed layer may be formed by electroless plating, or if desired by a sputtering process, or both may be used. The plating layer may be formed by electrolytic plating, but an embodiment thereof is not limited thereto, and may be formed by electroless plating and/or sputtering.

The adhesive film 250 may include various insulating materials having adhesive properties. For example, the adhesive film 250 may include epoxy resin, polyimide, silicone resin, or the like, but an embodiment thereof is not limited thereto. Metal particles such as copper (Cu) or silver (Ag) may be added to the adhesive film 250, but an embodiment thereof is not limited thereto. A die attach film (DAF) may be used as the adhesive film 250, but an embodiment thereof is not limited thereto.

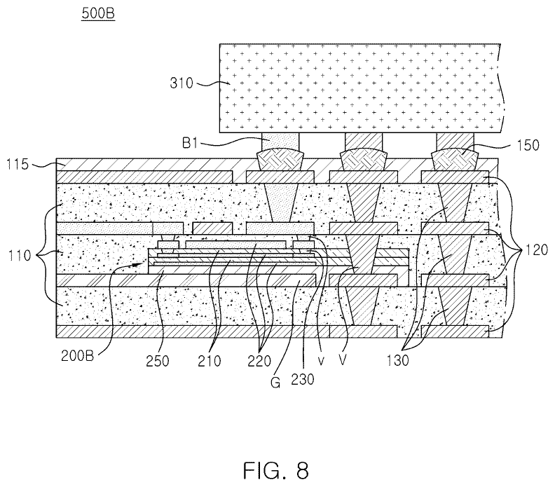

FIG. 8 is a cross-sectional diagram illustrating another example of a printed circuit board according to another example embodiment according to an example embodiment.

Referring to the drawings, a printed circuit board 500B according to another example may include a plurality of insulating layers 110, a plurality of wiring layers 120, and a plurality of via layers 130 as substrate bodies 110, 120, and 130, and a redistribution unit 200B may be built therein. The substrate bodies 110, 120, and 130 may be at least a portion of a multilayer package substrate structure. For example, the multilayer package substrate may be a double-sided built-up structure with respect to a core layer, and the substrate bodies 110, 120, and 130 illustrated in the drawings may represent a portion therein. Alternatively, the multilayer package substrate may be a coreless multilayer structure built-up without a core layer, and the substrate bodies 110, 120, and 130 illustrated in the drawings may represent a portion therein. However, an embodiment thereof is not limited thereto, and the substrate body 110, 120, and 130 may be at least a portion of another interposer substrate structure other than the multilayer package substrate structure.

A passivation layer 115 having an opening exposing at least a portion of the wiring layer 120 disposed on the uppermost side among the plurality of wiring layers 120 may be disposed on the insulating layer 110 disposed on the uppermost side among the plurality of insulating layers 110, and a semiconductor chip 310 may be disposed on the passivation layer 115. The semiconductor chip 310 may have a plurality of bumps B1 including a conductive material. The plurality of electrical connection metal 150 including a solder material may be disposed on each of the plurality of openings of the passivation layer 115, and the plurality of bumps B1 may be connected to the plurality of electrical connection metal 150, respectively. Accordingly, the semiconductor chip 310 may be mounted on the passivation layer 115.

A plurality of wiring layers 120 may include the ground pattern G, and the redistribution unit 200B may be attached to the ground pattern G through the adhesive film 250. The redistribution unit 200B may include a single-layer structure (see FIG. 6: 200-1) or a multilayer structure (see FIG. 7: 200-2) as described above. For example, the redistribution unit 200B may include one or more dielectric layers 210, one or more redistribution layers 220, and one or more redistribution via layers 230. The redistribution unit 200B may provide redistribution of a line or path transmitting a specific electric signal or power in the substrate body 110, 120, and 130. For example, connection between the semiconductor chip 310 and the plurality of wiring layers 120 may be possible through the redistribution unit 200B, and also net redistribution (NR) in the package structure may be performed. For example, the redistribution unit 200B may not be for die-to-die connection purposes. Accordingly, only one semiconductor chip 310 may be mounted on the passivation layer 115. However, an embodiment thereof is not limited thereto, and when the plurality of semiconductor chips are mounted, the redistribution unit 200B may provide die-to-die connection.

At least one connection via v included in the plurality of via layers 130 may connect one or more redistribution layers 220 and a plurality of wiring layers 120. At least one other connection via V included in the plurality of via layers 130 may penetrate the redistribution unit 200B and the adhesive film 250. The at least one other connection via V may be a connection via for signal connection between the plurality of wiring layers 120, but an embodiment thereof is not limited thereto.

Other descriptions are substantially the same as described through FIGS. 3 to 7, and accordingly, overlapping descriptions thereof will not be provided.

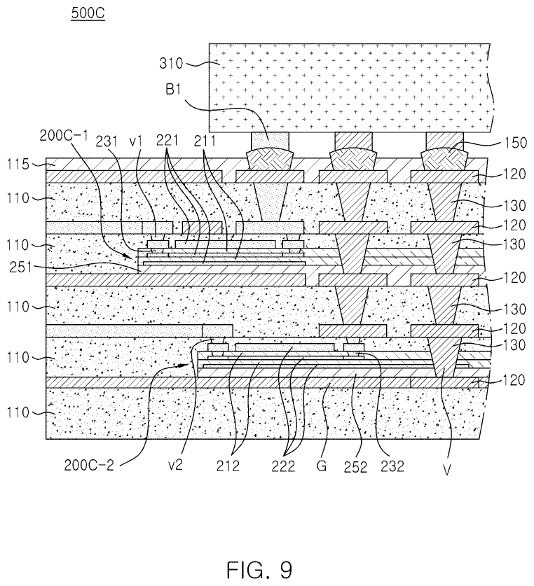

FIG. 9 is a cross-sectional diagram illustrating another example of a printed circuit board according to another example embodiment according to an example embodiment.

Referring to the drawings, in a printed circuit board 500C according to another example, the number of the plurality of insulating layers 110, the plurality of wiring layers 120, and the plurality of via layers 130 included in the substrate body 110, 120, 130 may be greater than those included in the printed circuit board 500B according to another example described above, and the plurality of redistribution units 200C-1 and 200C-2 may be embedded in the substrate bodies 110, 120, and 130. The plurality of redistribution units 200C-1 and 200C-2 may include a single-layer structure (see FIG. 6: 200-1) or a multilayer structure (see FIG. 7: 200-2) as described above, respectively. For example, the plurality of redistribution units 200C-1 and 200C-2 may include a first redistribution unit 200C-1 including one or more first dielectric layer 211, one or more first redistribution layers 221, and one or more first redistribution via layer 231, and a second redistribution unit 200C-2 including one or more second dielectric layer 212, one or more second redistribution layer 222, and one or more second redistribution via layer 232. The first and second redistribution units 200C-1 and 200C-2 may be attached to and embedded in the substrate body 110, 120, and 130 through the first and second adhesive films 251 and 252, respectively.

The first and second redistribution units 200C-1 and 200C-2 may be embedded in the substrate bodies 110, 120, and 130 at different levels with respect to the thickness direction, respectively. The plurality of wiring layers 120 may include a pair of third wiring patterns spaced apart from each other at substantially the same level with respect to the thickness direction, and a pair of fourth wiring patterns spaced apart from each other at the same level with respect to the thickness direction. The pair of third wiring patterns and the pair of fourth wiring patterns may be disposed at different levels with respect to the thickness direction. One or more first redistribution layers 221 may include a third redistribution pattern connected to a pair of third connection via v1 included in the plurality of via layers 130 and electrically connecting the pair of third wiring patterns to each other. One or more second redistribution layers 222 may include a fourth redistribution pattern electrically connecting the pair of fourth wiring patterns to the pair of fourth connection vias v2 included in the plurality of via layers 130. The pair of third wiring patterns and the third redistribution pattern may be disposed at different levels with respect to the thickness direction. The pair of fourth wiring patterns and the fourth redistribution pattern may be disposed at different levels with respect to the thickness direction.

The first and second redistribution units 200C-1 and 200C-2 may be bridge units for redistribution of lines or paths transmitting specific electrical signals or power in the substrate bodies 110, 120, and 130. For example, connection between the semiconductor chip 310 and the plurality of wiring layers 120 may be possible through the first and second redistribution units 200C-1 and 200C-2, and net redistribution (NR) in the package structure may also be performed. For example, the first and second redistribution units 200C-1 and 200C-2 may not be for die-to-die connection purposes. Accordingly, only one semiconductor chip 310 may be mounted on the passivation layer 115. However, an embodiment thereof is not limited thereto, and when a plurality of semiconductor chips are mounted, the first and/or second redistribution units 200C-1 and 200C-2 may also function as bridge units for die-to-die connection.

The plurality of wiring layers 120 may include the ground pattern G, and at least one ground connection via V included in the plurality of via layers 130 may penetrate the second redistribution unit 200C-2 and the second adhesive film 252 and may be connected to the ground pattern G. If desired, at least one ground connection via V may also penetrate the ground pattern included in one or more second redistribution layers 222. Such a ground connection via V may be a connection via for ground connection between the plurality of wiring layers 120, and/or between the plurality of wiring layers 120 and one or more redistribution layers 222, but an embodiment thereof is not limited thereto.

Other descriptions may be substantially the same as those described with reference to FIGS. 3 to 8, and accordingly, overlapping descriptions thereof will not be provided.

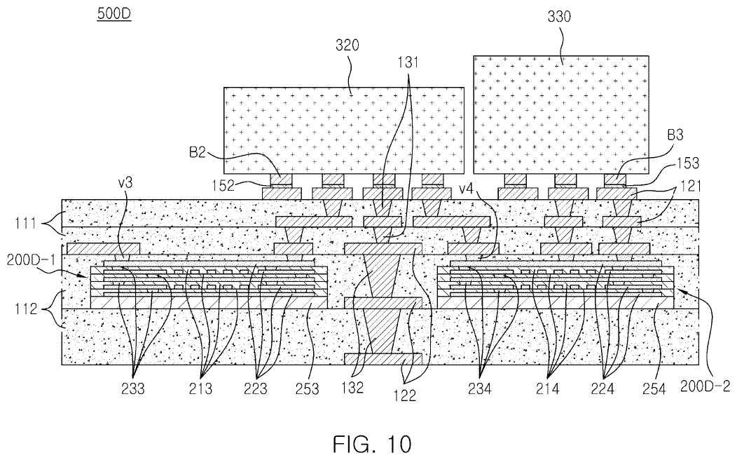

FIG. 10 is a cross-sectional diagram illustrating another example of a printed circuit board according to another example embodiment according to an example embodiment.

Referring to the drawings, a printed circuit board 500D according to another example may include a plurality of insulating layers 111 and 112, a plurality of wiring layers 121 and 122, and a plurality of via layers 131 and 132 as substrate bodies 111, 112, 121, 122, 131 and 132, and a plurality of redistribution units 200D-1 and 200D-2 may be embedded therein. The substrate bodies 111, 112, 121, 122, 131 and 132 may be at least a portion of a multilayer package substrate structure. For example, the multilayer package substrate may be a double-sided built-up structure with respect to the core layer, and the substrate bodies 111, 112, 121, 122, 131 and 132 illustrated in the drawing may represent a portion thereof. However, an embodiment thereof is not limited thereto, and the substrate bodies 111, 112, 121, 122, 131 and 132 may be at least a portion of another interposer substrate structure other than the multilayer package substrate structure.

The plurality of insulating layers 111 and 112 may include a plurality of first insulating layers 111 and a plurality of second insulating layers 112, and a thickness of each of the first insulating layers 111 may be less than a thickness of each of the second insulating layers 112. The plurality of wiring layers 121 and 122 may include a plurality of a first wiring layer 121 and a plurality of a second wiring layer 122, and each of the first wiring layer 121 may have a smaller average pitch than that of each of the second wiring layer 122. The plurality of via layers 131 and 132 may include a plurality of first via layers 131 and a plurality of second via layers 132, and each of the first via layer 131 may have an average diameter smaller than that of each of the second via layer 132. For example, the substrate bodies 111, 112, 121, 122, 131 and 132 may have a 2.nD package substrate structure. Also, the description of the plurality of insulating layers 110, the plurality of wiring layers 120, and the plurality of via layers 130 may be also applied to the plurality of insulating layers 111 and 112, the plurality of wiring layers 121 and 122, and the plurality of via layers 131 and 132, respectively.

A plurality of semiconductor chips 320 and 330 may be mounted on the first insulating layer 111 disposed on the uppermost side of the plurality of first insulating layers 111, respectively. The plurality of semiconductor chips 320 and 330 may be the same types of chip or different types of chips, and for example, the plurality of semiconductor chips 320 and 330 may be application-specific integrated circuit (ASIC), high bandwidth memory (HBM), or the like, respectively, but an embodiment thereof is not limited thereto. The plurality of semiconductor chips 320 and 330 may be connected to at least a portion of the first wiring layer 121 disposed on the uppermost side of the plurality of first wiring layers 121 through a plurality of bumps B2 and B3 and a plurality of electrical connection metals 152 and 153, respectively. Each of the plurality of bumps B2 and B3 may include a conductive material, and each of the plurality of electrical connection metals 152 and 153 may include a solder material, but an embodiment thereof is not limited thereto.

Each of the plurality of redistribution units 200D-1 and 200D-2 may include a single-layer structure (see FIG. 6: 200-1) or a multilayer structure (see FIG. 7: 200-2) as described above. For example, the plurality of redistribution units 200D-1 and 200D-2 may include a third redistribution unit 200D-1 including one or more third dielectric layers 213, one or more third redistribution layers 223 and one or more third redistribution via layer 233, and a fourth redistribution unit 200D-2 including one or more fourth dielectric layers 214, one or more fourth redistribution layers 224 and one or more fourth redistribution via layer 234. The third and fourth redistribution units 200D-1 and 200D-2 may be attached to and embedded in the substrate bodies 111, 112, 121, 122, 131 and 132, respectively, through third and fourth adhesive films 253 and 254.

The third and fourth redistribution units 200D-1 and 200D-2 may be embedded in the substrate bodies 111, 112, 121, 122, 131 and 132 at substantially the same level with respect to the thickness direction. The plurality of second wiring layer 122 may include a pair of fifth wiring patterns spaced apart from each other at substantially the same level with respect to the thickness direction, and a pair of sixth wiring patterns spaced apart from each other at the same level with respect to the thickness direction. The pair of fifth wiring patterns and the pair of sixth wiring patterns may be disposed at substantially the same level with respect to the thickness direction. One or more third redistribution layers 223 may include a fifth redistribution pattern connected to a pair of fifth connection via v3 included in the plurality of second via layers 132 and electrically connecting the pair of fifth wiring patterns to each other. One or more fourth redistribution layers 224 may include a sixth redistribution pattern connected to the sixth connections via v4 included in the plurality of second via layers 132 and electrically connecting the pair of sixth wiring patterns to each other. The pair of fifth wiring patterns and the fifth redistribution pattern may be disposed at different levels in the thickness direction. The pair of sixth wiring patterns and the sixth redistribution pattern may be disposed at different levels in the thickness direction.

Redistribution and/or die-to-die connection may be performed through the third and fourth redistribution units 200D-1 and 200D-2. For example, the third redistribution unit 200D-1 may provide redistribution of a line or a path for transmitting a specific electrical signal or power in the substrate bodies 111, 112, 121, 122, 131, and 132. For example, connection between the first semiconductor chip 320 and the plurality of wiring layers 121 and 122 may be possible through the third redistribution unit 200D-1, and also net redistribution (NR) in the package structure may be performed. Also, the fourth redistribution unit 200D-2 may provide a line or a path for transmitting a specific electrical signal or power between the plurality of semiconductor chips 320 and 330. For example, die to die (DtD) connection may be performed through the fourth redistribution unit 200D-2.

Other descriptions may be substantially the same as those described with reference to FIGS. 3 to 9, and accordingly, overlapping descriptions thereof will not be provided.

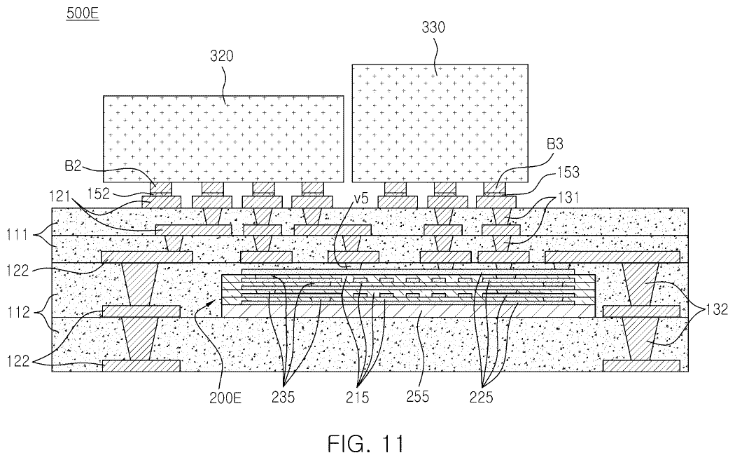

FIG. 11 is a cross-sectional diagram illustrating another example of a printed circuit board according to another example embodiment according to an example embodiment.

Referring to the drawings, in a printed circuit board 500E according to another example, instead of the plurality of redistribution units 200D-1, 200D-2, one redistribution unit 200E may be embedded in the substrate bodies 111, 112, 121, 122, 131, and 132, differently from the printed circuit board 500B according to another example described above. The redistribution unit 200E may include a single-layer structure (see FIG. 6: 200-1) or a multilayer structure (see FIG. 7: 200-2) as described above. For example, the redistribution unit 200E may include a fifth redistribution unit 200E including one or more fifth redistribution layers 225 and one or more fifth redistribution via layers 235. The fifth redistribution unit 200E may be attached to and embedded in the substrate body 111, 112, 121, 122, 131 and 132 through the fifth adhesive film 255. One or more fifth redistribution layers 225 may include at least one redistribution pattern resolving tangles of at least one pair of wiring patterns included in the plurality of wiring layers 121 and 122. At least one redistribution pattern may be connected to at least one pair of wiring patterns included in the plurality of wiring layers 121 and 122 through at least one pair of connection via v5 included in the plurality of via layers 131 and 132, respectively.

Both redistribution and die-to-die connection may be performed through the fifth redistribution unit 200E. For example, the fifth redistribution unit 200E may provide redistribution of a line or a path transmitting a specific electrical signal or power in the substrate bodies 111, 112, 121, 122, 131 and 132. For example, connection between the first semiconductor chip 320 and the plurality of wiring layers 121 and 122 may be possible through the fifth redistribution unit 200E, and net redistribution (NR) in the package structure may also be performed. Also, the fifth redistribution unit 200E may provide a line or a path transmitting a specific electrical signal or power between a plurality of semiconductor chips 320 and 330. For example, die to die (DtD) connection may also be performed through the fifth redistribution unit 200E.

Other descriptions may be substantially the same as those described with reference to FIGS. 3 to 10, and accordingly, overlapping description thereof will not be provided.

According to the aforementioned example embodiments, a printed circuit board which may effectively relieve wiring tangles and may thus reduce an increase in the number of layers may be provided.

A thickness, width, length, pitch, depth, or the like, may be measured using a scanning microscope or optical microscope with respect to a cross-section of a printed circuit board polished or cut out. The cross-section may be a vertical cross-section or a horizontal cross-section, and each value may be measured with respect to the required cross-section. When the value is not constant, the value may be determined as an average value of values measured at five arbitrary points. The width of the upper end and/or lower end of the via may be measured on a cross-section taken along the central axis of the via in the thickness direction. The depth of the via may be measured as the distance from the upper end to the lower end of the via on a cross-section taken along the central axis of the substrate in the thickness direction.

In the present disclosure, the term “covering” may include covering entirely and also covering at least a portion, and may also include covering directly and also covering indirectly. Also, the term “filling” may include filling completely and also filling roughly, and may include, for example, the presence of some gaps or voids. Also, the expression of surrounding may include not only the case of completely surrounding, but also the case of surrounding a portion and the case of roughly surrounding. Also, exposing may include completely exposing, and also partially exposing, and exposure may indicate being exposed from embedding the corresponding component. For example, opening exposing a pad may indicate exposing the pad from the resist layer, and a surface treatment layer may be disposed on the exposed pad.

In the present disclosure, process errors, positional deviations, and measurement errors occurring in the manufacturing process may be included. For example, the notion that the line width, distance, thickness, and height are substantially the same may include case in which the elements are completely the same in numerical sense, and also case in which the elements may have similar values. Also, the notion of “having substantially a predetermined shape” may include case of having almost the same shape and also having a similar shape.

In the present disclosure, process errors, positional deviations, and measurement errors occurring in the manufacturing process may be included. For example, the notion that the line width, distance, thickness, and height are substantially the same may include case in which the elements are completely the same in numerical sense, and also case in which the elements may have similar values. Also, the notion of “having substantially a predetermined shape” may include case of having almost the same shape and also having a similar shape.

In the present disclosure, the same insulating material may indicate completely the same insulating material and also the same type of insulating material. Accordingly, the composition of the insulating material may be substantially the same, but the specific composition ratio thereof may be slightly different.

The terms “lower side,” “lower portion,” “lower surface,” and the like, may be used to refer to a surface formed in a downward direction with reference to a cross-section in the diagrams for ease of description, the terms “upper side,” “upper portion,” “upper surfaces,” and the like, may be used to refer to a surface formed in an upward direction, and the terms “side portion,” “side surface,” and the like, may be used to refer to a surface formed taken in the direction perpendicular to a upper surface and lower surface. The terms, however, may be defined as above for ease of description, and the scope of right of the example embodiments is not particularly limited to the above terms.

In the example embodiments, the term “connected” may not only refer to “directly connected” but also include “indirectly connected” by means of an adhesive layer, or the like. Also, the term “electrically connected” may include both of the case in which elements are “physically connected” and the case in which elements are “not physically connected.” Further, the terms “first,” “second,” and the like may be used to distinguish one element from the other, and may not limit a sequence and/or an importance, or others, in relation to the elements. In some cases, a first element may be referred to as a second element, and similarly, a second element may be referred to as a first element without departing from the scope of right of the example embodiments.

In the example embodiments, the term “example embodiment” may not refer to one same example embodiment, and may be provided to describe and emphasize different unique features of each example embodiment. The above suggested example embodiments may be implemented do not exclude the possibilities of combination with features of other example embodiments. For example, even though the features described in one example embodiment are not described in the other example embodiment, the description may be understood as relevant to the other example embodiment unless otherwise indicated.

An expression used in the singular encompasses the expression of the plural, unless it has a clearly different meaning in the context.

While the example embodiments have been illustrated and described above, it will be apparent to those skilled in the art that modifications and variations could be made without departing from the scope of the present disclosure as defined by the appended claims.

What is claimed is:

1. A printed circuit board, comprising:
a substrate body including a plurality of wiring layers and a plurality of via layers, wherein the plurality of wiring layers include a pair of first wiring patterns spaced apart from each other and disposed at substantially the same level as each other with respect to a thickness direction; and
a first redistribution unit including one or more first redistribution layers, wherein the one or more first redistribution layers include a first redistribution pattern disposed at a level different from a level of the pair of first wiring patterns with respect to the thickness direction,
wherein the first redistribution unit is embedded in the substrate body, and
wherein the first redistribution pattern connects the pair of first wiring patterns to each other.

2. The printed circuit board of claim 1,
wherein the plurality of via layers include a pair of first connection vias connecting the first redistribution pattern to each of the pair of first wiring patterns.

3. The printed circuit board of claim 1,
wherein the plurality of wiring layers further include a pair of second wiring patterns spaced apart from each other and disposed at substantially the same level as each other with respect to the thickness direction,
wherein the one or more first redistribution layers further include a second redistribution pattern disposed at a level different from a level of the pair of second wiring patterns with respect to the thickness direction, and
wherein the second redistribution pattern connects the pair of second wiring patterns to each other.

4. The printed circuit board of claim 3, wherein the plurality of via layers include a pair of second connection vias connecting the second redistribution pattern to each of the pair of second wiring patterns.

5. The printed circuit board of claim 3,
wherein the pair of first wiring patterns and the pair of second wiring patterns are disposed at substantially the same level as each other with respect to the thickness direction, and
wherein, when the substrate body and the first redistribution unit are viewed from the thickness direction, the second redistribution pattern overlaps at least one of the pair of first wiring patterns.

6. The printed circuit board of claim 3,
wherein a virtual line that connects two ends of the pair of first wiring patterns, spaced at a minimum distance, intersects with a virtual line that connects two ends of the pair of second wiring patterns, spaced at a minimum distance.

7. The printed circuit board of claim 3, wherein the first and second redistribution patterns are spaced apart from each other and disposed at substantially the same level as each other with respect to the thickness direction.

8. The printed circuit board of claim 3, wherein the first and second redistribution patterns are disposed at different levels from each other with respect to the thickness direction.

9. The printed circuit board of claim 1, further comprising:
a second redistribution unit including one or more second redistribution layers,
wherein the plurality of wiring layers further include a pair of third wiring patterns spaced apart from each other and disposed at substantially the same level as each other with respect to the thickness direction,
wherein the one or more second redistribution layers include a third redistribution pattern disposed at a level different from a level of the pair of third wiring patterns with respect to the thickness direction, and
wherein the third redistribution pattern connects the pair of third wiring patterns to each other.

10. The printed circuit board of claim 9, wherein the plurality of via layers include a pair of third connection vias connecting the third redistribution pattern to each of the pair of third wiring patterns.

11. The printed circuit board of claim 9,
wherein the pair of third wiring patterns are disposed at a level different from the level of the pair of first wiring patterns with respect to the thickness direction, and
wherein the second redistribution unit is embedded in the substrate body and disposed at a level different from a level of the first redistribution unit with respect to the thickness direction.

12. The printed circuit board of claim 9,
wherein the pair of third wiring patterns are disposed at substantially the same level as the level of the pair of first wiring patterns with respect to the thickness direction, and
wherein the second redistribution unit is embedded in the substrate body and disposed at substantially the same level as a level of the first redistribution unit with respect to the thickness direction.

13. The printed circuit board of claim 1,
wherein the plurality of wiring layers include a ground pattern, and
wherein the first redistribution unit is attached to the ground pattern through an adhesive film.

14. The printed circuit board of claim 13, wherein the plurality of via layers include a ground connection via penetrating the first redistribution unit and the adhesive film and connected to the ground pattern.

15. The printed circuit board of claim 13,
wherein the one or more first redistribution layers are configured as a plurality of first redistribution layers, and
wherein the first redistribution unit includes a plurality of first redistribution via layers connecting the plurality of first redistribution layers to each other.

16. The printed circuit board of claim 15, wherein the plurality of first redistribution layers include a structure in which one first redistribution layer including a redistribution pattern and another first redistribution layer including a ground pattern are laminated alternately.

17. The printed circuit board of claim 15,
wherein, among the plurality of first redistribution layers, a first redistribution layer disposed on an uppermost side includes a pair of first connection pads connected to each of the pair of first wiring patterns, and
wherein, among the plurality of first redistribution layers, a thickness of the first redistribution layer disposed on the uppermost side is greater than a thickness of each of the other first redistribution layers.

18. A printed circuit board, comprising:
a pair of first wiring patterns disposed and spaced apart from each other on substantially the same layer;
a pair of second wiring patterns disposed and spaced apart from each other on substantially the same layer;
a first redistribution unit including a first redistribution pattern disposed in a different layer from the pair of first wiring patterns and connecting the pair of first wiring patterns to each other; and
a second redistribution unit including a second redistribution pattern disposed in a different layer from the pair of second wiring patterns and connecting the pair of second wiring patterns to each other.

19. The printed circuit board of claim 18,
wherein the printed circuit board has a multilayer wiring substrate structure including a plurality of insulating layers, a plurality of wiring layers, and a plurality of via layers,
wherein the plurality of wiring layers include the first and second wiring patterns, and
wherein the first and second redistribution units are buried in the plurality of insulating layers at substantially the same level as each other with respect to the thickness direction, or are buried in the plurality of insulating layers at different levels from each other with respect to the thickness direction.
